(19) United States
(12) Patent Application Publication
(10) Pub. No.: US 2016/0163767 A1
(43) Pub. Date: Jun. 9, 2016

(54) NANOCOMPOSITE-BASED NON-VOLATILE MEMORY DEVICE AND METHOD FOR MANUFACTURING SAME

(71) Applicant: INDUSTRY-UNIVERSITY COOPERATION FOUNDATION HANYANG UNIVERSITY, Seoul (KR)

(72) Inventors: Taewhan KIM, Seoul (KR); Dongyeol YUN, Incheon (KR); Daeuk LEE, Goyang-si (KR); Narayanasany Sabari ARUL, Seoul (KR)

(21) Appl. No.: 14/906,711

(22) PCT Filed: Apr. 15, 2014
(86) PCT No.: PCT/KR2014/003269

§ 371 Date: Jan. 21, 2016

(30) Foreign Application Priority Data
Sep. 6, 2013 (KR) 10-2013-0106938

(51) Int. Cl. H01L 27/28; H01L 51/00

(52) U.S. Cl. CPC H01L 27/28; H01L 51/0002

(57) ABSTRACT

The present invention provides a nanocomposite-based non-volatile memory device and a method for manufacturing the same, the nanocomposite-based non-volatile memory device comprising: a substrate; a lower electrode formed on the substrate; an active layer formed on the lower electrode and made of an insulating organic material, in which a polycrystalline four-element nanocomposite is dispersed; and an upper electrode formed on the active layer.

According to the present invention, a non-volatile memory device can be provided which has an increased ON/OFF ratio and thereby substantially decreases sensing errors resulting from small noise of a circuit, and a non-volatile memory can be easily manufactured at comparatively low costs.

### TECHNICAL FIELD

The present invention relates to a nanocomposite-based non-volatile memory device and a method for manufacturing the same.

### BACKGROUND ART

In general, non-volatile memory devices have a non-volatile characteristic of retaining data memorized in a cell even when power is disconnected, and include a mask ROM, a PROM, an EPROM, an EEPROM, a flash memory, etc.

Meanwhile, the non-volatile memory devices store data through a conductivity change caused by an external electric field, and according to Non-Patent Document 1 (Min Ho Lee, Jae Hun Jung, Jae Ho Shim, Tae Whan Kim, Electrical bistabilities and carrier transport mechanisms of write-once-readmany-times memory devices fabricated utilizing ZnO nanoparticles embedded in a polystyrene layer, Applied Physics Letters, 95(14), pp. 143301-1-143301-3 (2009)) and Non-Patent Document 2 (Dong Ick Son, Dong Hee Park, Jong Bin Kim, Ji-Won Choi, Tae Whan Kim, Bistable Organic Memory Device with Gold Nanoparticles Embedded in a Conducting Poly(N-vinylcarbazole) Colloids Hybrid, The Journal of Physical Chemistry C, 115(5), pp. 2341-2348 (2011)), two-element nanoparticles (NPs) such as ZnO, SnO₂, etc. or single-element nanoparticles such as Au are dispersed on a substrate, thereby forming an organic active layer, and data is stored using a change in the electric conductivity caused by capturing and releasing charges in the active layer. Since each nanoparticle has limited capturing and releasing capabilities, a size of the change in conductivity of the organic memory device using two-element or single-element nanoparticles is not more than 1⁶.

Alternatively, there is a method for increasing the size of conductivity of the organic memory device using a buffer layer, but in this case, there is a limitation in which the size of the conductivity change of the organic memory device is not more than 1⁶.

According to the conventional art described above, a memory device has a low ON/OFF ratio, and therefore a sensing error may not be reduced as needed.

Thus, it is necessary to conduct studies on nanoparticles and the electrical property of the organic memory device using the nanoparticles to solve the limitation of the conductivity change in the memory device.

### DISCLOSURE

### Technical Problem

The present invention is directed to providing a nanocomposite-based non-volatile memory device having an increased ON/OFF ratio.

The present invention is directed to providing a method for manufacturing a nanocomposite-based non-volatile memory device that can be easily manufactured using a low temperature process at low cost.

However, problems to be solved by the present invention are not limited to the problems described above, and other problems not described will be clearly understood by those of ordinary skill in the art from the following descriptions.

### Technical Solution

To achieve the above-described subjects, one aspect of the present invention provides a nanocomposite-based non-volatile memory device which includes a substrate, a lower electrode formed on the substrate, an active layer formed on the lower electrode and made of an insulating organic material in which a polycrystalline four-element nanocomposite is dispersed, and an upper electrode formed on the active layer.

Another aspect of the present invention provides a method for manufacturing a nanocomposite-based non-volatile memory device which includes preparing a lower electrode-coated substrate; forming an active layer by coating the lower electrode with a mixed solution of a four-element nanocomposite and an insulating organic material; and forming an upper electrode on the active layer.

Still another aspect of the present invention provides a non-volatile memory device, which includes a first electrode, a second electrode and an active layer formed between the first electrode and the second electrode, wherein the active layer includes an insulating organic material in which a polycrystalline four-element nanocomposite is dispersed.

### Advantageous Effects

According to the present invention, a non-volatile memory device having an increased ON/OFF ratio that can dramatically reduce a sensing error caused by less noise of a circuit and a method for easily manufacturing a non-volatile memory device at relatively low cost may be provided.

### DESCRIPTION OF DRAWINGS

FIG. 1 is a block diagram of a nanocomposite-based non-volatile memory device according to an exemplary embodiment of the present invention.

FIG. 2 is a process diagram illustrating the formation of polycrystalline CZTS (Cu, Zn, Sn, S) nanoparticles and the manufacture of an organic memory device using the same according to an exemplary embodiment of the present invention.

FIG. 3 shows energy dispersive X-ray spectroscopy (a) and an X-ray diffraction image (b) of polycrystalline CZTS nanoparticles according to an exemplary embodiment of the present invention.

FIG. 4 shows transmission electron microscopy images a polycrystalline CZTS nanoparticles-included PMMA organic layer and a polycrystalline CZTS lattice shape according to an exemplary embodiment of the present invention.

FIG. 5 shows a graph (a) showing charge capturing and releasing abilities of CZTS nanoparticles of a non-volatile memory device and a graph (b) showing a current-voltage (I-V) relationship when a natural oxide layer is generated in an upper Al electrode according to an exemplary embodiment of the present invention.

FIG. 6 is a graph showing a current-time (I-t) switching measurement result obtained by bending of a non-volatile memory device according to an exemplary embodiment of the present invention.

FIG. 7 is a graph showing a current-retention stress measurement result of a non-volatile memory device according to an exemplary embodiment of the present invention.

FIG. 8 is an Auger electron spectroscopy (AES) graph that can confirm the presence of an oxide layer at an interface between an Al electrode and an organic layer including CZTS nanoparticles according to an exemplary embodiment of the present invention.

FIG. 9 shows a graph showing a current-voltage (I-V) fitting result to confirm a mechanism of a non-volatile memory device according to an exemplary embodiment of the present invention.

### MODES OF THE INVENTION

Hereinafter, with reference to the accompanying drawings, a nanocomposite-based non-volatile memory device of the present invention and a method for manufacturing the same will be described in detail for easy implementations by those of ordinary skill in the art to which the present invention belongs.

The present invention was designed to dramatically reduce a sensing error by improving an ON/OFF ratio of a non-volatile memory device using nanoparticles. Since the nanoparticles have excellent chemical, optical and electrical properties, studies on the nanoparticles are ongoing, receiving great attentions from optical, electrical and electronic fields. A lot of studies on the nanoparticles having such excellent properties are progressing in solar cell and display fields, and studies for applying the nanoparticles to memory devices are also actively progressing.

However, to realize by the introduction of nanoparticles the electrical property which has remained impossible to achieve by a conventional memory device, in the present invention, nanoparticles are designed in directions which are somewhat further different from other approaches.

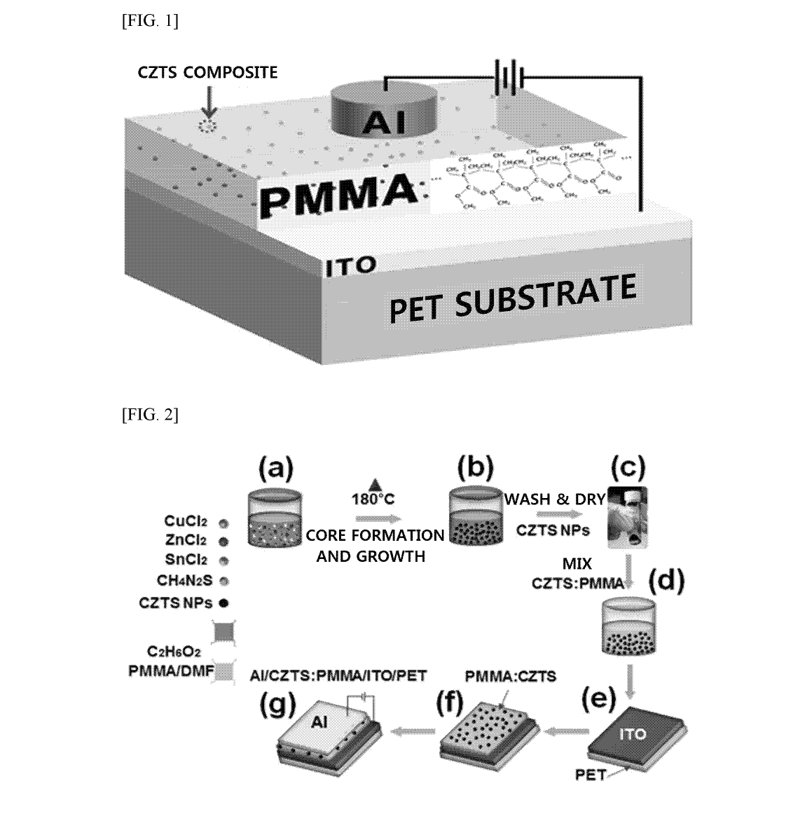

Referring to FIG. 1, an example of a schematic block diagram of a nanocomposite-based non-volatile memory device of the present invention can be seen.

That is, the nanocomposite-based non-volatile memory device of the present invention includes a substrate, a lower electrode formed on the substrate, an active layer formed on the lower electrode and made of an organic material in which a polycrystalline four-element nanocomposite is dispersed, and an upper electrode formed on the active layer. In FIG. 1, an example using PET as the substrate, ITO as the lower electrode, PMMA as the active layer, CZTS nanoparticles as the nanocomposite, and Al as the upper electrode is illustrated.

In the present invention, a film formed on a specific substrate or a surface of another film is expressed as “formed on.” Accordingly, it should be interpreted that the expression “the lower electrode is formed on the substrate” includes both phenomena of formation on a surface of the substrate and of formation on the surface of another film placed on the substrate. The interpretation of the above-described expression is applied in the same manner throughout the present invention.

The substrate is made of an insulating inorganic material or an insulating organic material. The insulating inorganic material may be at least any one of Si, GaAs, InP, Al2O3, SiC, glass and quartz. Also, the insulating organic material may be at least any one of polyethylene terephthalate (PET), polystyrene (PS), polyimide (PI), polyvinylchloride (PVC), polyvinylpyrrolidone (PVP), polyethylene (PE), polycarbonate (PC), and polydimethylsiloxane (PDMS). When the substrate made of the insulating organic material is used, flexibility may be increased.

The lower electrode formed on the substrate may be made of at least one selected from Al, Au, Cu, Pt, Ag, W, Ni, Zn, Ti, Zr, Hf, Cd, Pd, Al-doped ZnO, Ga-doped ZnO, In and Ga-doped ZnO, F-doped ZnO, Al-doped ZnO/Ag/Al-doped ZnO, Ga-doped ZnO/Ag/Ga-doped ZnO, In-doped ZnO/Ag/In-doped ZnO, In and Ga-doped ZnO/Ag/In, and Ga-doped ZnO, but the present invention is not limited thereto. The lower electrode may be formed by a method such as thermal evaporation. A method of forming an electrode through the method such as thermal evaporation is an already known technique in the art, and thus detail description on this method will be omitted.

The active layer formed on the lower electrode is made of an insulating organic material and a polycrystalline four-element nanocomposite, and the polycrystalline four-element nanocomposite is dispersed in the insulating organic material. The nanocomposite dispersed in the organic material captures and releases electrons, such a property influences the change in electric conductivity, and such a change causes the difference in current flowed in the device. Here, the conductivity is retained constant until an external electric field for making the conductivity change of the device is applied, and by this phenomenon, the device serves as a memory device. Also, the capturing of charges in a polycrystalline interface between elements of the nanocomposite in a low conductive state may contribute to the further enhancement of the conductivity change for the ON/OFF states by collaborating with the function of capturing electrons of the nanocomposite.

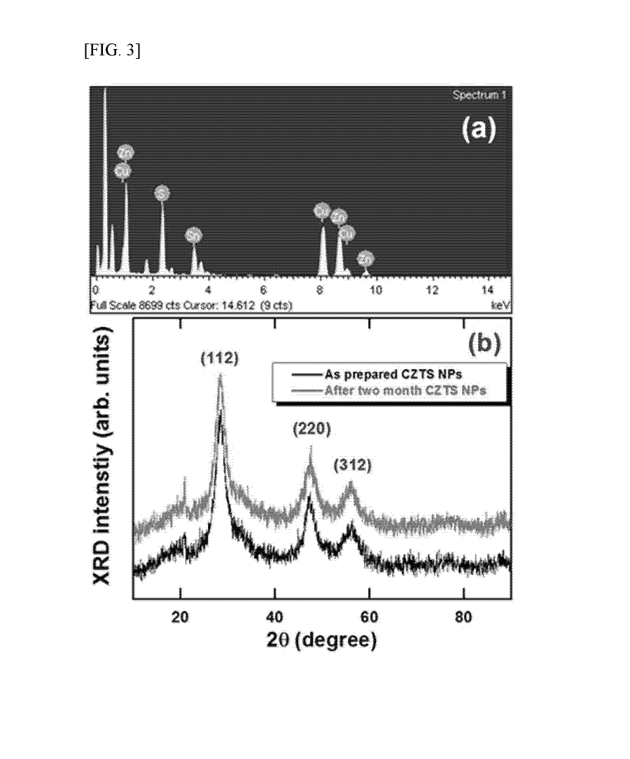

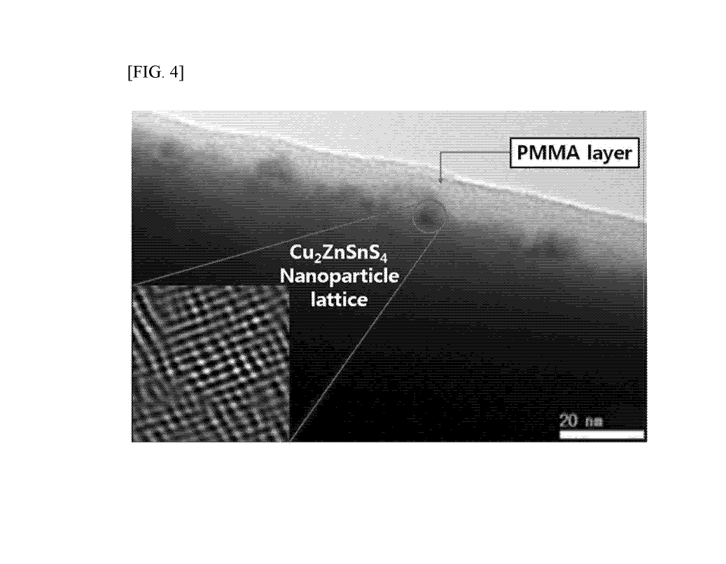

In FIG. 3, energy dispersive X-ray spectroscopy (a) and an X-ray diffraction image (b) of a polycrystalline CZTS (Cu, Zn, Sn and S) nanocomposite according to an exemplary embodiment of the present invention are shown, and in FIG. 4, transmission electron microscopy images of a PMMA organic layer including a polycrystalline CZTS nanocomposite and a polycrystalline CZTS lattice shape are shown. Referring to FIG. 4, it can be confirmed that the nanocomposite present in the active layer of the memory device of the present invention is composed of four elements and has polycrystallinity.

The insulating organic material may be one or more selected from the group consisting of polymethylmetacrylate (PMMA), polystyrene (PS), polyimide (PI), parylene, polyvinylpyrrolidone (PVP), poly-(N-vinylcarbazole) (PVK), polyethylene (PE), polyvinylalcohol (PVA), polycarbonate (PC), polyethyleneterephthalate (PET), polybisphenol A and a fluorine-based polymer compound, but the present invention is not limited thereto.

Also, the polycrystalline four-element nanocomposite may be selected from CuZnSnS, InGaAsP, ZnAgInS, CuZnInS, InGaAlAs, ZnCdSSe, CdTeInP, CdSeZnTe, CdSeZnS, AgInSeZn, ZnSeInP, InPCdSe, InPZnSe, InPZnTe, InPCdS, InPZnS and InGaZnO, but the present invention is not limited thereto. Here, one or more of each of the four elements constituting the four-element nanocomposite may be combined to form the nanocomposite. For example, the CuZnSnS of the polycrystalline four-element nanocompositesmeans that the elements constituting the nanocomposite are four types consisting of Cu, Zn, Sn and S, and the number of each element combined together in a nanocomposite may vary. That is, the CuZnSnS may be understood as the concept including a material such as CuzZnSnS₄. The rest of the four-element nanocomposites may also be understood within the same concepts, and thus detail descriptions on these nanocomposites will be omitted.

When the active layer is made of an organic material including single-element, two-element or three-element nanoparticles, it is difficult to expect a high ON/OFF ratio due to the lack of sites for capturing charges, however, when the active layer is made of an organic material including a polycrystalline four-element nanocomposite a high ON/OFF ratio may be obtained due to a charge-capturing ability at an interface between each element of the nanocomposite and the polycrystalline as described above, and thus the enhancement of an electrical property is expected. Also, as long as the desired effect of the present invention is brought out, the case in which the active layer is made of an organic material including a nanocomposite composed of four or more elements is not intended to be excluded.

To obtain a suitable ON/OFF ratio, a thickness of the active layer may be 20 nm to 200 nm. This is because, when the thickness is too small, a short may occur, and when the thickness is too large, an insulator property may be exhibited.

Also, a size of the polycrystalline four-element nanocomposite may be 1 nm to 100 nm. That is, when the size is too large, the conductivity is enhanced too much to reduce a charge-capturing ability, and therefore, a phenomenon of capturing and releasing charges at a predetermined voltage or less needs to be suitably maintained.

The active layer may be formed by coating the lower electrode with a mixed solution of the four-element nanocomposite and the insulating organic material.

Specifically, the active layer may be formed by spin coating, roll coating, spray coating, flow coating, electrostatic coating, inkjet printing, nozzle printing, dip coating, electrophoretic deposition, tape casting, screen printing, pad printing, doctor blade coating, gravure printing, gravure offset printing, or a Langmuir-Blogett method.

In the mixed solution of the four-element nanocomposite and the insulating organic material, a solvent may be included, and as such a solvent, an aqueous solvent, a non-aqueous solvent or a mixed solvent thereof may be included. For example, the solvent may include but is not limited to, water; an alcohol solvent such as methanol, ethanol, propanol or isopropanol; an ether solvent such as diethylether, dipropylether, or tetrahydrofuran; an alcohol ether solvent such as ethyleneglycol, propyleneglycol, ethyleneglycolmonomethylether, ethyleneglycolmonoethylether, or ethyleneglycolmonobutylether; a ketone solvent such as acetone, methylethylketone, methylisobutylketone, or cyclohexanone; an amide solvent such as N-methyl-2-pyrrilidinone, 2-pyrrilidinone, N-methylformamide, or N,N-dimethylformamide; a sulfoxide solvent such as dimethylsulfoxide or diethylsulfoxide; a sulfone solvent such as diethyl sulfone or tetramethylene sulfone; a nitrile solvent such as acetonitrile or benzonitrile; an amine solvent such as alkylamine, cyclic amine or aromatic amine; an ester solvent such as methyl butylate, ethylbutylate or propylpropionate; a carboxylic acid ester solvent such as ethyl acetate or butylacetate; an aromatic hydrocarbon solvent such as benzene, ethylbenzene, chlorobenzene, toluene, or xylene; an aliphatic hydrocarbon solvent such as hexane, heptane, or cyclohexane; a halogenated hydrocarbon solvent such as chloroform, tetrachloroethylene. carbontetrachloride, dichloromethane, or dichloroethane; and a mixed solvent composed of the composite thereof.

To form the active layer, a process of coating a lower electrode with the mixed solution and removing a solvent included in the mixed solution through thermal-treatment at a low temperature in the range of 90 to 150° C. may be performed.

Also, the four-element nanocomposite may be synthesized by thermal-treating a mixture of a precursor material of the four-element nanocomposite and an organic solvent. Here, the thermal treatment may be performed at 90 to 150° C. to prevent the chemical bonds and transformation of the appearance of the material.

The precursor material may be an inorganic acid salt such as a fluoride salt, a chloride salt, a nitrate, a sulfate, or a carbonate, or an organic acid salt such as an acetate of a metal, a metal hydrate or a metal complex. The metal component may include but is not limited to, one or more components selected from the group consisting of Ru, Rh, Cu, Ag, Au, Pd, Pt, Sb, Sc, Sr, V, Cu, Y, Ce, Mo, W, Fe, Zr, Co, Ni, Zn,Cd, Mn, Ca, Ba, Cs, Cr, Mg, Ti, Al, In, Sn, Se, Fe, Cd, Te, Ga, Gd, Ge, Dy, Pr, Sm, Ho, Lu, Tb, Eu, Nd, La, Ta, Hf, Er and Yb.

An upper electrode may be formed on the active layer and made of at least one selected from Al, Au, Cu, Pt, Ag, W, Ni, Zn, TI, Zr, Hf, Cd, Pd, carbon nanotube (CNT), graphene and graphite, but the present invention is not limited thereto.

The upper electrode may be formed by a method such as thermal evaporation. The method for forming an electrode through thermal evaporation is an already known technique in the art, and thus the detail description of this technique will be omitted.

A metal oxide layer may be further included at least between the active layer and the lower electrode, or between the active layer and the upper electrode.

The metal oxide layer may be formed by thermal and chemical evaporation, and made of at least one selected from SiO₂, ZrO₂, HfO₂, Y₂O₃, Al₂O₃, BaTiO₃, WO₃, SrTiO₃, (Ba₁₋ₓSrₓ)TiO₃, Ba(Ti_{0.8}Sn_{0.2})TiO₃, (Ba,Pb)(ZrTi)O₃, (Pb₁₋ₓLaₓ)TiO₃, (Pb,La)(Zr,Ti)O₃, and (PbZr₁₋ₓ)TiₓO₃, but the present invention is not limited thereto.

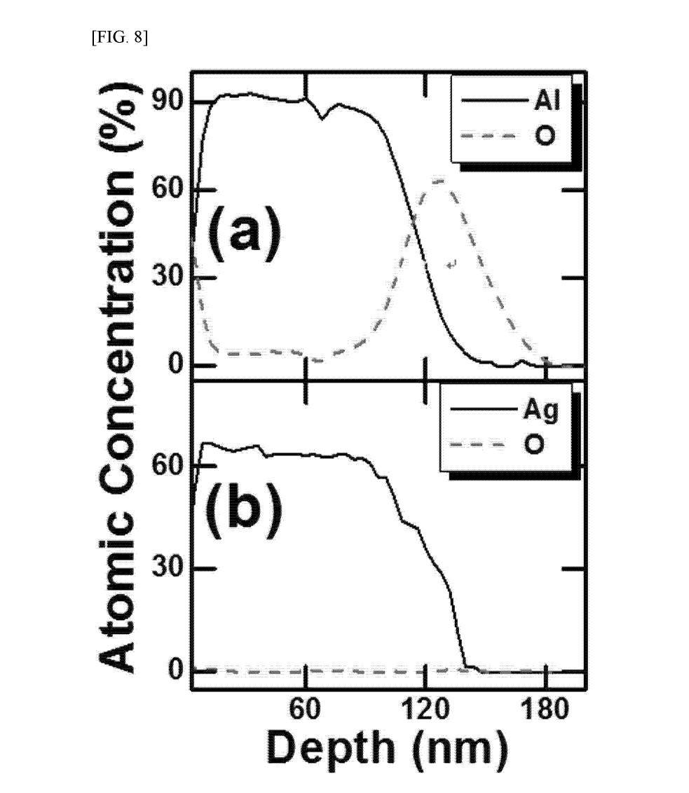

FIG. 8 shows an Auger electron spectroscopy (AES) graph which can identify the presence of a metal oxide layer at an interface between an Al electrode and an organic layer including a CZTS nanocomposite according to an exemplary embodiment of the present invention.

Due to the presence of the metal oxide layer, an ON/OFF ratio in terms of the performance of the memory device may be moderately enhanced. Also, the active layer made of the nanocomposite can be protected from an external environment such as humidity, and therefore the reliability of the device performance can be increased.

The nanocomposite-based non-volatile memory device according to the present invention records data by capturing electrons injected through the upper electrode and the lower electrode to the nanocomposite and the polycrystalline interface. The nanocomposite is surrounded by an insulating organic material, and therefore it is difficult to release electrons captured in the nanocomposite to the outside. Also, it is also difficult to release electrons captured at polycrystalline interface. That is, once captured, the electrons are difficult to be released to the outside, and thus the recording state can be retained for a long time.

A method of capturing electrons to the nanocomposite is performed by supplying a write voltage using the upper electrode and the lower electrode. That is, data may be recorded by supplying the write voltage only once, and the once-recorded data is stored for a long time. Also, as described above, the nanocomposite-based non-volatile memory device according to the present invention can be manufactured only using simple processes such as thermal evaporation and spin coating and thus can be mass-produced at low cost. Consequently, the nanocomposite-based non-volatile memory device has the merits of providing a large storage capacity at low cost and storing once-recorded data for a long time.

Hereinafter, the present invention will be described in detail with reference to examples. However, the following examples are merely examples to explain the present invention in further detail, and the scope of the present invention is not limited to the examples.

### EXAMPLES

1. Synthesis of CZTS Nanocomposite

(1) 2 mmol of copper(II)chloridedehydrate (CuCl₂₂O), 1 mmol of zinc(II)chloride (ZnCl₂), 1 mmol of tin(IV)chloridetetrahydrate (SnCl₄₂O), and ₈ mmol of thiourea (CH₄N₂S) were added to 40 ml of ethylene glycol and sufficiently mixed using a magnetic stirrer (FIG. 2(a)).

(2) The mixed solution was put into a high pressure stainless steel container and sealed and then thermally treated at 180° C. for 6 hours (FIG. 2(b)).

(3) After the thermally-treated solution was slowly cooled at room temperature, a by-product was rapidly separated using a centrifugal separator and then washed again with deionized water to remove. To remove other by-products generated during synthesis, the resultant product was washed with ethanol several times. Afterward, to completely remove the solvent, the resultant product was dried in a vacuum oven at 80° C., thereby obtaining a CZTS nanocomposite (FIG. 2(c)).

(4) To identify components of the obtained CZTS nanocomposite, energy dispersive X-ray spectroscopy and X-ray diffraction analysis were performed (FIG. 3).

2. Manufacture of Nanocomposite-Based Non-Volatile Memory Device

(1) 0.003 g of the previously-obtained CZTS nanocomposite, 0.087 g of PMMA, and 2.813 g of N,N-dimethylformamide (DMF) as a solvent were mixed and stirred with a spin bar to be sufficiently mixed (FIG. 2(d)).

(2) As a result of confirming the distribution of the CZTS nanocomposite dispersed in PMMA in the DMF solvent by an observation using transmission electron microscopy, it was confirmed that a CZTS lattice structure has a polycrystalline lattice (FIG. 4).

(3) A PET substrate formed by coating PET used as a lower electrode with ITO was washed sequentially with methanol, deionized water and isopropanol through an ultrasonication each for 15 minutes to remove and wash impurities attached to the substrate. The washed substrate was dried using an N₂ gas having no chemical reaction (FIG. 2(e)).

(4) The ITO-coated flexible substrate was sequentially spin-coated with the mixed solution prepared in (1) at room temperature for 5 seconds at 500 rpm, 40 seconds at 3000 rpm, and 5 seconds at 500 rpm. A solvent was removed by thermal treatment in a vacuum oven at a low temperature of 90° C. for 30 minutes, thereby forming a PMMA organic layer in which the CZTS nanocomposite is dispersed (FIG. 2(f)).

(5) A flexible nanocomposite-based non-volatile memory device having a PMMA organic layer in which a CZTS nanocomposite is dispersed was completed by placing an upper electrode on the completed PMMA organic layer using a mask (FIG. 2(g)).

3. Evaluation of Performance of Nanocomposite-Based Non-Volatile Memory Device

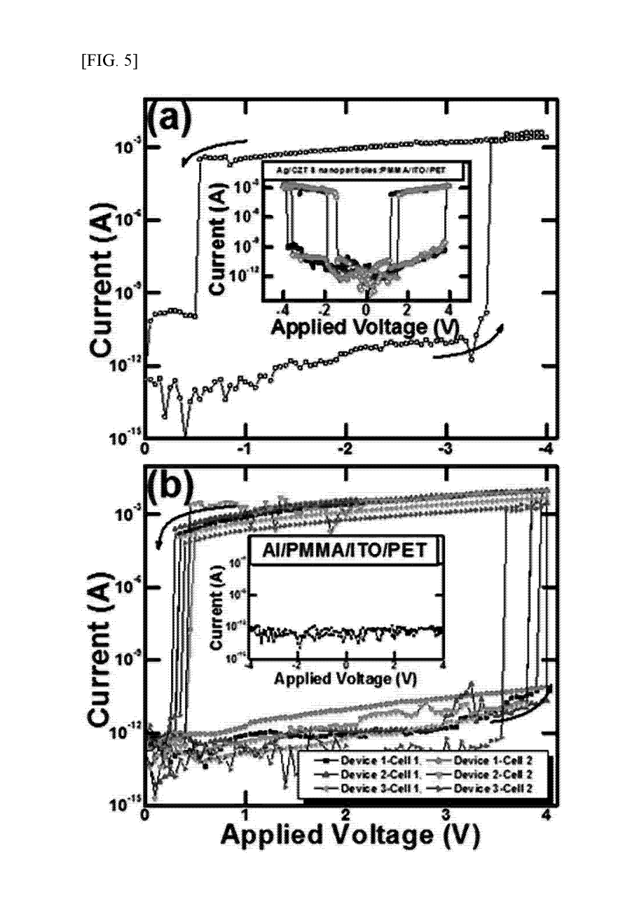

(1) A current-voltage property of the memory device having the PMMA organic layer including the CZTS nanocomposite disclosed in the present invention may be confirmed through FIG. 5. It is seen that an ON/OFF ratio which is a ratio of a high conductivity represented as ON and a low conductivity represented as OFF when the memory device is manufactured using the PMMA organic layer in which polycrystalline CZTS nanoparticles are dispersed as the active layer is far higher.

(2) As a result of measuring the current-voltage property as shown in the drawing included in FIG. 5(a) of a device manufactured using Al and Ag having a similar energy work function and having a chemical reaction to confirm if the ON/OFF ratio caused by a natural oxide layer of the upper Al electrode is higher, it was reconfirmed that the polycrystalline CZTS nanocomposite increases the ON/OFF ratio. Also, as a result of measuring a current-voltage property as shown in the drawing included in FIG. 5(b) of a device manufactured not including a CZTS nanocomposite, it was reconfirmed that the polycrystalline CZTS nanocomposite increases the ON/OFF ratio.

(3) In the initial state of the device, a low conductivity state in which a current of 10⁻⁹ to 10⁻¹⁴A flows is defined as an OFF state. As charges are captured in each element and a polycrystalline interface of the CZTS nanocomposite in the OFF state, the charge flow blocks the flow from the lower electrode to the upper electrode. When the size of voltage in a forward (+) direction is increased in the OFF state, as shown in FIG. 5, the current is abruptly increased to about 10⁻³A, and thus the state transitions to a state having high conductivity. Such a high conductivity state is defined as an ON state, and the voltage in this state is called a write voltage.

(4) Following the supply of the write voltage, as shown in FIG. 5, in the device, a high current of 10⁻³ to 10⁻⁴A flows, and such an ON state is continuously retained without the supply of a voltage. This allows the capture of charges in each element and the polycrystalline interface of the CZTS nanocomposite saturated, and the saturated environment and the CZTS nanocomposite serves as a type of conductive bridge through which the electrons can flow to allow a high current to flow.

(5) As shown in FIG. 5, at a low voltage of about 0.4 V, the ON state which is a high current state transitions to the OFF state which is a low conductivity state. Since there are no sufficient energy for releasing the captured charges and tunneling through a PMMA barrier, the conductive bridge function of (4) is destroyed, and the flow of charges is cut, thereby retaining a low current state.

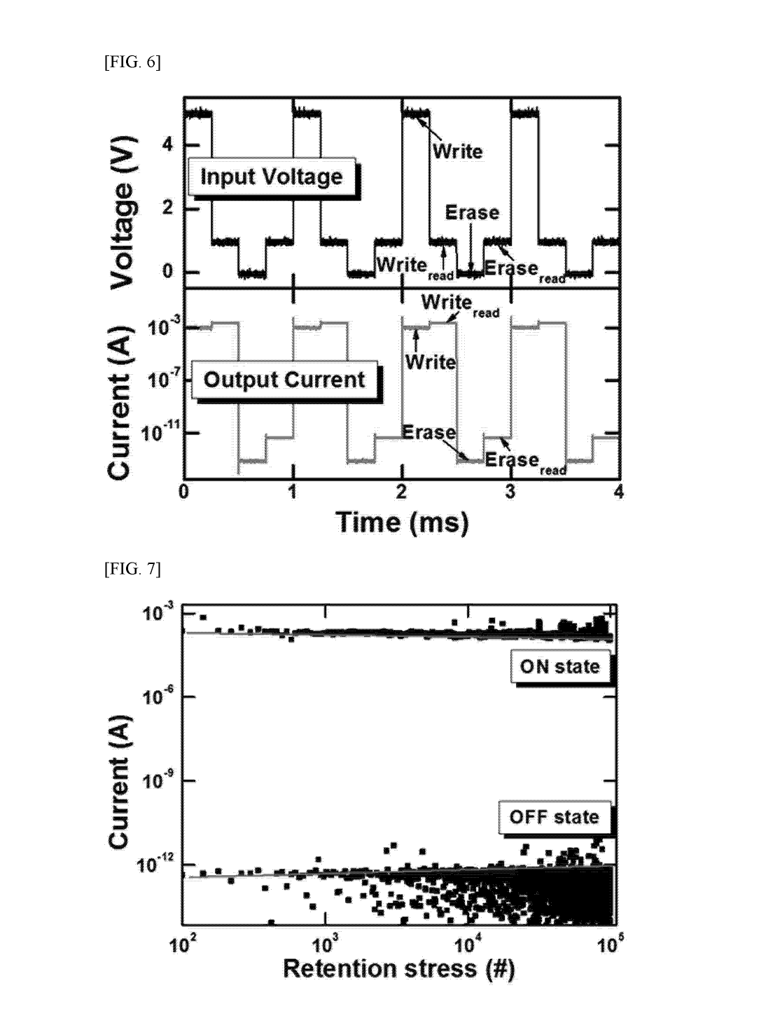

(6) To determine the state of the device, as shown in FIG. 6, a write or erase voltage of 5 or −1 V is supplied, and then a read voltage of 1 V is supplied. When the voltage state due to the read voltage is an OFF state, a current of about 10⁻¹¹ to 10⁻¹³A flows as shown in FIG. 6, and when in an ON state, a current of about 10⁻³ to 10⁻⁴A flows as shown in FIG. 6. The ON/OFF current ratio at the read voltage of 1 V has the maximum value of about 10¹⁰. The size of the read voltage is not determined, and generally, a voltage having the highest ON/OFF current ratio is selected.

(7) FIG. 7 shows that, although reading on the device is repeated, the ON/OFF ratio of about 10¹⁰ can be retained at least 10⁵ times .

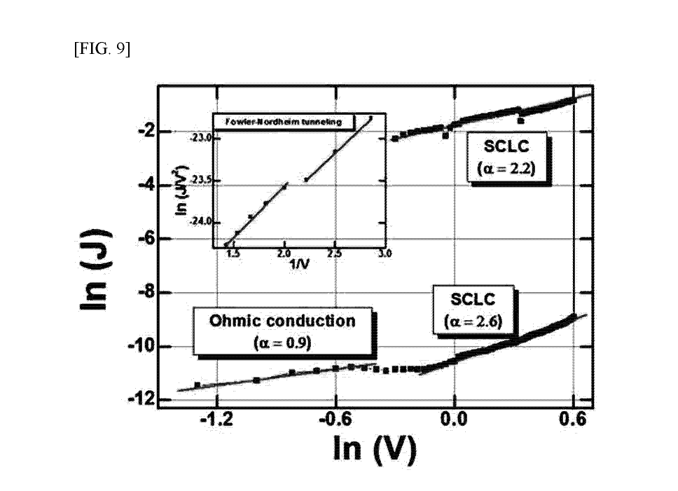

(8) FIG. 9 shows the evaluation of the memory mechanisms of (4) and (5) by fitting their electrical properties to a conventional theory. As shown in FIG. 9, it is confirmed that the mechanisms fit the conventional theory well.

4. Review of the Results

A state of the non-volatile memory device manufactured using the PMMA organic active layer in which the polycrystalline CZTS nanocomposite is dispersed is memorized by the change in conductivity caused by an external electric field. The memory device has an ON state with a high conductivity and an OFF state with a low conductivity and has a very high ON/OFF ratio of 10¹¹ by the capture and release of charges in the polycrystalline CZTS nanocomposite. Since the memory device having the PMMA organic active layer in which the polycrystalline CZTS nanocomposite is dispersed uses spin coating and low temperature process methods performed on an ITO-coated flexible PET substrate, the device can be easily manufactured at low cost and make up for the shortcomings of the treatment with high heat. The memory device has a high ON/OFF ratio, and therefore a sensing error caused by less noise of the circuit may be greatly reduced. In the present invention, a method for forming a polycrystalline CZTS nanocomposite having a high ON/OFF ratio, a method for simply manufacturing the non-volatile memory device using the PMMA organic active layer in which the particles are dispersed using a low temperature process at low cost, and an operating principle are presented.

1. A nanocomposite-based non-volatile memory device, comprising:
a substrate;
a lower electrode formed on the substrate;
an active layer formed on the lower electrode and made of an insulating organic material in which a polycrystalline four-element nanocomposite is dispersed; and
an upper electrode formed on the active layer.

2. The device of claim 1, further comprising:
a metal oxide layer formed at least between the active layer and the lower electrode or between the active layer and the upper electrode.

3. The device of claim I, wherein the substrate is an insulating organic substrate.

4. The device of claim 1, wherein the lower electrode is made of at least one selected from Al, Au, Cu, Pt, Ag, W, Ni, Zn, Ti, Zr, Hf, Cd, Pd, Al-doped ZnO, Ga-doped ZnO, In and Ga-doped ZnO, F-doped ZnO, Al-doped ZnO/Ag/Al-doped ZnO, Ga-doped ZnO/Ag/Ga-doped ZnO, In-doped ZnO/Ag/In-doped ZnO, In and Ga-doped ZnO/Ag/In and Ga-doped ZnO.

5. The device of claim 1, wherein the insulating organic material is one or more selected from the group consisting of polymethylmetacrylate (PMMA), polystyrene (PS), polyimide (PI), parylene, polyvinylpyrrolidone (PVP), poly-(N-vinylcarbazole) (PVK), polyethylene (PE), polyvinylalcohol (PVA), polycarbonate (PC), polyethyleneterephthalate (PET), and polybisphenol A.

6. The device of claim 1, wherein the polycrystalline four-element nanocomposite is selected from CuZnSnS, InGaAsP, ZnAgInS, CuZnInS, InGaAlAs, ZnCdSSe, CdTelnP, CdSeZnTe, CdSeZnS, AgInSeZn, ZnSeInP, InPCdSe, InPZnTe, InPZnTe, InPCdS, InPZnS and InGaZnO.

7. The device of claim 1, wherein the active layer has a thickness of 20 nm to 200 nm.

8. The device of claim 1, wherein the polycrystalline four-element nanocomposite has a size of 1 nm to 100 nm.

9. The device of claim 1, wherein the upper electrode is made of at least one selected from Al, Au, Cu, Pt, Ag, W, Ni, Zn, Ti, Zr, Hf, Cd, Pd, CNT, graphene, and graphite.

10. The device of claim 2, wherein the metal oxide layer is made of at least one selected from SiO₂, ZrO₂, HfO₂, Y₂O₃, Al₂O₃, BaTiO₃, WO₃, SrTiO₃, (Ba₁₋ₓSrₓ)TiO₃, Ba(Ti_{0.8}Sn_{0.2})TiO₃, (Ba,Pb)(ZrTi)O₃, (Pb₁₋ₓLaₓ)TiO₃, (Pb,La)(Zr,Ti)O₃, and (PbZr₁₋ₓ)TiₓO₃.

11. A method for manufacturing a nanocomposite-based non-volatile memory device, comprising:
preparing a lower electrode-coated substrate;
forming an active layer by coating the lower electrode with a mixed solution of a four-element nanocomposite and an insulating organic material; and
forming an upper electrode on the active layer.

12. The method of claim 11, wherein the four-element nanocomposite is formed by thermal-treating a mixture of a precursor material of the four-element nanocomposite and a solvent.

13. The method of claim 11, wherein the active layer is formed by spin coating, roll coating, spray coating, flow coating, electrostatic coating, inkjet printing, nozzle printing, dip coating, electrophoretic deposition, tape casting, screen printing, pad printing, doctor blade coating, gravure printing, gravure offset printing, or a Langmuir-Blogett method.

14. The method of claim 11, wherein the forming of the active layer includes thermal treatment performed at 90 to 150° C.

15. The method of claim 12, wherein the thermal treatment is performed at 90 to 150° C.

16. A non-volatile memory device, comprising:
a first electrode;
a second electrode; and
an active layer between the first electrode and the second electrode,
wherein the active layer includes an insulating organic material in which a polycrystalline four-element nanocomposite is dispersed.

17. The device of claim 16, further comprising:
a metal oxide layer at least between the active layer and the first electrode or between the active layer and the second electrode.

18. The device of claim 16, wherein the polycrystalline four-element nanocomposite is selected from CuZnSnS, InGaAsP, ZnAgInS, CuZnInS, InGaAlAs, ZnCdSSe, CdTeInP, CdSeZnTe, CdSeZnS, AgInSeZn, ZnSeInP, InPCdSe, InWnSe, InPZnTe, InPCdS, InPZnS and InGaZnO.

19. The device of claim 16, wherein the active layer has a thickness of 20 nm to 200 nm.

20. The device of claim 16, wherein the polycrystalline four-element nanocomposite has a size of 1 nm to 100 nm.
